(19) United States
(12) Patent Application Publication
(10) Pub. No.: US 2020/0325572 A1
(43) Pub. Date: Oct. 15, 2020

(54) Sputtering Target, Method For Manufacturing Sputtering Target, Amorphous Film, Method For Manufacturing Amorphous Film, Crystalline Film And Method For Manufacturing Crystalline Film

(71) Applicant: JX Nippon Mining & Metals Corporation, Chiyoda-ku, Tokyo (JP)

(72) Inventors: Takashi Kakeno, Ibaraki (JP); Toshihiro Kuge, Ibaraki (JP)

(21) Appl. No.: 16/082,591

(22) PCT Filed: Dec. 4, 2017
(86) PCT No.: PCT/JP2017/043535

§ 371 Date: Sep. 6, 2018

(30) Foreign Application Priority Data
Mar. 31, 2017 (JP) 2017-072024

(51) Int. Cl. C23C 14/34

(52) U.S. Cl. CPC C23C 14/3414

(57) ABSTRACT

The present invention provides a sputtering target which is an oxide target. The sputtering target comprises In, Ta and Ti, wherein a content of Ta satisfies Ta/(In+Ta+Ti)=0.08 to 0.45 at %, and a content of Ti satisfies Ti/(In+Ta+Ti)=0.03 to 1.25 at %.

### TECHNICAL FIELD

The present invention is related to a sputtering target, a method for manufacturing sputtering target, an amorphous film, a method for manufacturing amorphous film, a crystalline film and a method for manufacturing crystalline film.

### BACKGROUND ART

A transparent conductive oxide film has good optical transparency and good conductivity, and therefore, it is put to various uses. Representatives of the transparent conductive oxide film include zinc oxide system oxide film and tin oxide system oxide film, but indium oxide system oxide film is the most common film and it is widely known as ITO (Indium Tin Oxide) film. ITO film has characteristics such as low resistivity, high transmittance and micro-fabrication easiness, and they are better than those of other transparent conductive films. Accordingly, ITO film is used in various technical fields including a display electrode for flat panel display.

Examples of a method for manufacturing the transparent conductive oxide film include ion plating method, evaporation method and sputtering method. Among these methods, the sputtering method particularly has the advantage of better control of film thickness.

In recent years, as the sputtering target used for manufacturing the transparent conductive oxide film by the sputtering method, research and development for the sputtering target comprising Ta and Ti as additive elements have been done from the view point of controlling refractive index of the transparent conductive oxide film, and the like.

As such techniques, for example, Patent Literature 1 discloses an indium oxide system sputtering target characterized in that the sputtering target comprises tantalum oxide and titanium oxide of 5.2 to 9.2 mass % in total amount, mass ratio of titanium oxide/tantalum oxide is 0.022 to 0.160, the balance is indium oxide, a relative density is 97% or more and specific resistance is 5×10⁻⁴Ω·cm or less. It also discloses that, with this structure, an indium oxide system sputtering target having high relative density and low specific resistance, comprising large-scale sintered body in which the transparent conductive oxide film can be applied to a DC sputtering method on an industrial scale for mass production, can be provided.

### CITATION LIST

### Patent Literature

[PTL 1] Japanese Patent No. 5170009

### SUMMARY OF INVENTION

### Problem to be Solved by the Present Invention

However, target materials having high density cannot be produced by conventional method for manufacturing sputtering target by using sintered body provided by pulverization, granulating, and sintering of raw material particles comprising indium oxide as main ingredient, tantalum oxide and titanium oxide. Accordingly, there is still room for the development.

Therefore, the object of the present invention is to provide a sputtering target comprising In, Ta and Ti, and having high density. Also, the other object of the present invention is to provide a sputtering target comprising In, Ta, Ti and Sn, and having high density.

### Solution to Problem

In order to achieve the above object, the inventors of the present invention have conducted intensive studies and have found that the sputtering target comprising In, Ta and Ti, and having high density can be provided by controlling a content of Ta and Ti in the target to prescribed atom ratio (at %). In addition, the inventors of the present invention have found that the sputtering target comprising In, Ta, Ti and Sn, and having high density can be provided by controlling a content of Ta, Ti and Sn in the target to prescribed atom ratio (at %).

One or more embodiments of the present application have been completed based on the aforementioned knowledge, and relate to, in one aspect, a sputtering target, being an oxide target, comprising In, Ta and Ti, wherein a content of Ta satisfies Ta/(In+Ta+Ti)=0.08 to 0.45 at %, and a content of Ti satisfies Ti/(In+Ta+Ti)=0.03 to 1.25 at %.

In another embodiment of the sputtering target of the present application, the sputtering target has a relative density of 98.5% or more.

In still another embodiment of the sputtering target of the present application, the sputtering target has a relative density of 98.8% or more.

In still another embodiment of the sputtering target of the present application, the sputtering target has a relative density of 98.9% or more.

In still another embodiment of the sputtering target of the present application, the number of a phase having high density of Ta or Ti in an area analysis with FE-EPMA and having a maximum diameter of 5 μm or more is 3 or less within a view of 50 μm×50 μm SEM image.

One or more embodiments of the present application also relates to, in still another aspect, a method for manufacturing the sputtering target of the present application, comprising
a step of molding raw material particles, and
a step of sintering the molded raw material particles comprising,
   a step of heating the molded raw material particles to 1300 to 1400° C. at a temperature rising speed of 1 to 5° C./minute,
   a step of maintaining the temperature for 5 to 60 hours, and
   a step of dropping the temperature at a temperature dropping speed of 0.1 to 3° C./minute.

In another embodiment of the method for manufacturing the sputtering target of the present application, the raw material particles comprise Ta₂O₅ and TiO₂, each of Ta₂O₅ and TiO₂ having an average particle diameters D50 of 2.0 μm or less and a BET specific surface area of 2.0 m²/g or more.

One or more embodiments of the present application also relates to, in still another aspect, a sputtering target, being an oxide target, comprising In, Ta, Ti and Sn, wherein a content of Ta satisfies Ta/(In+Ta+Ti+Sn)=0.08 to 0.45 at %, a content of Ti satisfies Ti/(In+Ta+Ti+Sn)=0.03 to 1.25 at %, and a content of Sn satisfies Sn/(In+Ta+Ti+Sn)=0.04 to 0.40 at %.

In still another embodiment of the sputtering target of the present application, the sputtering target has a relative density of 98.5% or more.

In still another embodiment of the sputtering target of the present application, the sputtering target has a relative density of 98.8% or more.

In still another embodiment of the sputtering target of the present application, the sputtering target has a relative density of 98.9% or more.

In still another embodiment of the sputtering target of the present application, wherein the number of a phase having high density of Ta, Ti or Sn in an area analysis with FE-EPMA and having a maximum diameter of 5 μm or more is 3 or less within a view of 50 μm×50 μm SEM image.

One or more embodiments of the present application also relates to, in another aspect, a method for manufacturing the sputtering target of the present application, comprising
a step of molding raw material particles, and
a step of sintering the molded raw material particles comprising,
   a step of heating the molded raw material particles to 1300 to 1400° C. at a temperature rising speed of 1 to 5° C./minute,
   a step of maintaining the temperature for 5 to 60 hours, and
   a step of dropping the temperature at a temperature dropping speed of 0.1 to 3° C./minute.

In another embodiment of the method for manufacturing the sputtering target of the present application, the raw material particles comprise Ta₂O₅, TiO₂ and SnO₂, each of Ta₂O₅, TiO₂ and SnO₂ having an average particle diameters D50 of 2.0 μm or less and a BET specific surface area of 2.0 m²/g or more.

One or more embodiments of the present application also relates to, in still another aspect, a method for manufacturing an amorphous film, comprising a step of sputtering a substrate by using the sputtering target of the present application, to produce the amorphous film.

One or more embodiments of the present application also relates to, in still another aspect, an amorphous film having the same composition with the sputtering target of the present application.

One or more embodiments of the present application also relates to, in still another aspect, a method for manufacturing a crystalline film, comprising a step of annealing the amorphous film of the present application, to crystallize the amorphous film.

One or more embodiments of the present application also relates to, in still another aspect, a crystalline film having the same composition with the sputtering target of the present application.

### Advantageous Effect of Invention

According to one or more embodiments of the present application, a sputtering target comprising In, Ta and Ti, and having high density can be provided. In addition, a sputtering target comprising In, Ta, Ti and Sn, and having high density can be provided.

### BRIEF DESCRIPTION OF THE DRAWINGS

FIG. 1 shows an example of a structure image in an area analysis with FE-EPMA.

FIG. 2 shows schematic diagrams indicating an example in which sub-phase can be positioned within a circle with a diameter of 5 μm in the structure image (an example having excellent dispersability) and an example in which sub-phase cannot be positioned within a circle with a diameter of 5 μm in the structure image (an example having poor dispersability).

### DESCRIPTION OF EMBODIMENTS

### <Sputtering Target Comprising In, Ta and Ti>

In the sputtering target according to one or more embodiments of the present application, the sputtering target is an oxide target, and comprises In, Ta and Ti, and a content of Ta satisfies Ta/(In+Ta+Ti)=0.08 to 0.45 at %, and a content of Ti satisfies Ti/(In+Ta+Ti)=0.03 to 1.25 at %. The sputtering target is an oxide target mainly containing indium oxide.

With regard to the content of Ta in the target, when Ta/(In+Ta+Ti) is less than 0.08 at %, the problem of low density of the target arises, and when Ta/(In+Ta+Ti) is more than 0.45 at %, the problem of high resistance of a film produced by the sputtering method arises. With regard to the content of Ti in the target, when Ti/(In+Ta+Ti) is less than 0.03 at %, the problem of low density of the target arises, and when Ti/(In+Ta+Ti) is more than 1.25 at %, the problem of high resistance of a film produced by the sputtering method arises. The contents of Ta and Ti in the target preferably satisfy Ta/(In+Ta+Ti)=0.10 to 0.40 at % and Ti/(In+Ta+Ti)=0.40 to 1.05 at %, and more preferably satisfy Ta/(In+Ta+Ti)=0.15 to 0.35 at % and Ti/(In+Ta+Ti)=0.70 to 0.95 at %.

In the sputtering target of the present application, high density is achieved by controlling the contents of Ta and Ti. The sputtering target of the present application has a relative density of preferably 98.5% or more, more preferably 98.8% or more, still more preferably 98.9% or more. The relative density is a value calculated by the formula: (actual measurement density/true density)×100 (%). The actual measurement density can be calculated by each measurement value of weight/volume, but in general, Archimedes method is used and the present invention applies the Archimedes method. The true density can be calculated by converting analysis value (weight % ratio) of each element in the target to each oxide of In₂O₃, TiO₂, Ta₂O₅. The density of each oxide uses In₂O₃: 7.18 g/cm³, Ta₂O₅: 8.74 g/cm³, TiO₂: 4.26 g/cm³.

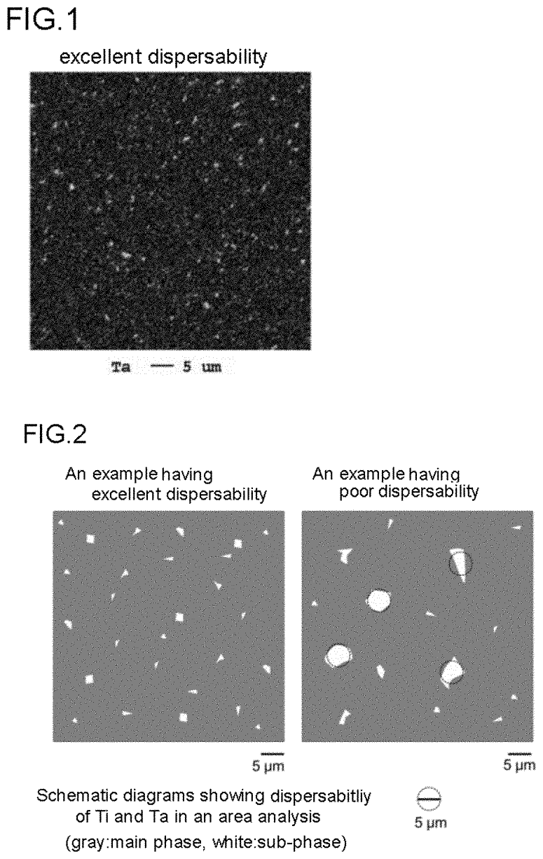

The sputtering target can be analyzed by an area analysis with FE-EPMA. In the sputtering target of the present application, when a structure image is observed by the area analysis of Ta or Ti with FE-EPMA, In₂O₃ phase which is a parent phase and a phase having higher density of Ta and Ti in the parent phase can be identified. Next, analysis value of density of Ta or Ti in the phase having higher density of Ta and Ti and analysis value of density of Ta or Ti in a phase surrounding it are compared. As the result, a phase, having analysis value ratio of density of Ta or Ti between the phase having higher density of Ta and Ti and the phase surrounding it (the analysis value ratio of density=the density in the phase having higher density of Ta and Ti/the density in the phase surrounding it) being 5 or more, is defined to be “the phase having high density of Ta and Ti”. “The phase having high density of Ta and Ti” is defined to be sub-phase and the phase surrounding the sub-phase is defined to be main phase. The number of the sub-phase having a maximum diameter of 5 μm or more in the target is preferably 3 or less within a view of 50 μm×50 μm SEM image. The number of the sub-phase having a maximum diameter of 4 μm or more in the target is more preferably 3 or less within a view of 50 μm×50 μm SEM image. With this structure, an irregular color in appearance of the target can be reduced and uniform composition of a film produced by sputtering method can be obtained. FIG. 1 shows an example of a structure image in an area analysis with FE-EPMA. In the area analysis, for example, as seen in FIG. 2 (schematic diagrams for dispersability of Ti and Ta with the area analysis: an example having excellent dispersability, an example having poor dispersability), the sub-phase in which a diameter cannot be positioned within a circle with a diameter of 5 μm in the structure image (the diameter that cannot be covered with a circle with a diameter of 5 μm) is defined to be a sub-phase having a maximum diameter of 5 μm or more. Further, with regard to a selection of observation field of view, it is preferable that three observation fields of view are optionally selected, and the number of the sub-phase having a maximum diameter of 5 μm or more in the target is 3 or less in each observation fields of view.

### <Sputtering Target Comprising In, Ta, Ti and Sn>

In the sputtering target according to one or more embodiments of the present application, the sputtering target is an oxide target, and comprises In, Ta, Ti and Sn, and a content of Ta satisfies Ta/(In+Ta+Ti+Sn)=0.08 to 0.45 at %, a content of Ti satisfies Ti/(In+Ta+Ti+Sn)=0.03 to 1.25 at % and a content of Sn satisfies Sn/(In+Ta+Ti+Sn)=0.04 to 0.40 at %. The sputtering target is an oxide target mainly containing indium oxide.

With regard to the content of Ta in the target, when Ta/(In+Ta+Ti+Sn) is less than 0.08 at %, the problem of low density of the target arises, and when Ta/(In+Ta+Ti+Sn) is more than 0.45 at %, the problem of high resistance of a film produced by the sputtering method arises. With regard to the content of Ti in the target, when Ti/(In+Ta+Ti+Sn) is less than 0.03 at %, the problem of low density of the target arises, and when Ti/(In+Ta+Ti+Sn) is more than 1.25 at %, the problem of high resistance of a film produced by the sputtering method arises. With regard to the content of Sn in the target, when Sn/(In+Ta+Ti+Sn) is less than 0.04 at %, the problem of low density of the target arises, and when Sn/(In+Ta+Ti+Sn) is more than 0.40 at %, the problem of high resistance of a film produced by the sputtering method arises. The contents of Ta, Ti and Sn in the target preferably satisfy Ta/(In+Ta+Ti+Sn)=0.10 to 0.40 at %, Ti/(In+Ta+Ti+Sn)=0.40 to 1.05 at % and Sn/(In+Ta+Ti+Sn)=0.15 to 0.35 at %, and more preferably satisfy Ta/(In+Ta+Ti+Sn)=0.15 to 0.35 at %, Ti/(In+Ta+Ti+Sn)=0.70 to 0.95 at % and Sn/(In+Ta+Ti+Sn)=0.20 to 0.30 at %.

In the present invention, “atom ratio (at %)” of Ta, Ti and Sn in the sputtering target is provided by a measurement with ICP method. Further, “atom ratio (at %)” of In is provided by subtracting the atom ratio (at %) of Ta, Ti and Sn from a whole.

In the sputtering target of the present application, high density is achieved by controlling the contents of Ta, Ti and Sn. The sputtering target of the present application has a relative density of preferably 98.5% or more, more preferably 98.8% or more, still more preferably 98.9% or more. The relative density is a value calculated by the formula: (actual measurement density/true density)×100 (%). The actual measurement density can be calculated by each measurement value of weight/volume, but in general, Archimedes method is used and the present invention applies the Archimedes method. The true density can be calculated by converting analysis value (weight % ratio) of each element in the target to each oxide of In₂O₃, SnO₂, TiO₂, Ta₂O₅. The density of each oxide uses In₂O₃: 7.18 g/cm³, SnO₂: 6.95 g/cm³, Ta₂O₅: 8.74 g/cm³, TiO₂: 4.26 g/cm³.

The sputtering target can be analyzed by an area analysis with FE-EPMA. In the sputtering target of the present application, when a structure image is observed by the area analysis of Ta, Ti or Sn with FE-EPMA, In₂O₃ and SnO₂ phase which is a parent phase and a phase having higher density of Ta, Ti or Sn in the parent phase can be identified. Next, analysis value of density of Ta, Ti or Sn in the phase having higher density of Ta, Ti or Sn and analysis value of density of Ta, Ti or Sn in a phase surrounding it are compared. As the result, a phase, having analysis value ratio of density of Ta, Ti or Sn between the phase having higher density of Ta, Ti or Sn and the phase surrounding it (the analysis value ratio of density=the density in the phase having higher density of Ta, Ti or Sn/the density in the phase surrounding it) being 5 or more, is defined to be “the phase having high density of Ta, Ti or Sn”. “The phase having high density of Ta, Ti or Sn” is defined to be sub-phase and the phase surrounding the sub-phase is defined to be main phase. The number of the sub-phase having a maximum diameter of 5 μm or more in the target is preferably 3 or less within a view of 50 μm×50 μm SEM image. The number of the sub-phase having a maximum diameter of 4 μm or more in the target is more preferably 3 or less within a view of 50 μm×50 μm SEM image. With this structure, an irregular color in appearance of the target can be reduced and uniform composition of a film produced by sputtering method can be obtained. FIG. 1 shows an example of a structure image in an area analysis with FE-EPMA. In the area analysis, for example, as seen in FIG. 2 (schematic diagrams for dispersability of Ti and Ta with the area analysis: an example having excellent dispersability, an example having poor dispersability), the sub-phase in which a diameter cannot be positioned within a circle with a diameter of 5 μm in the structure image (the diameter that cannot be covered with a circle with a diameter of 5 μm) is defined to be a sub-phase having a maximum diameter of 5 μm or more. Further, with regard to a selection of observation field of view, it is preferable that three observation fields of view is optionally selected, and the number of the sub-phase having a maximum diameter of 5 μm or more in the target is 3 or less in each observation fields of view.

### <Method for Manufacturing Sputtering Target>

Next, a method for manufacturing the sputtering target of the present application is explained hereinafter. At first, with regard to the method for manufacturing the sputtering target comprising In, Ta and Ti, of the present application, raw material particles consisting of indium oxide particles, tantalum oxide particles and titanium oxide particles are weighed and mixed in prescribed proportions. With regard to the method for manufacturing the sputtering target comprising In, Ta, Ti and Sn, of the present application, raw material particles consisting of indium oxide particles, tantalum oxide particles, titanium oxide particles and tin oxide particles are weighed and mixed in prescribed proportions.

Next, it is preferable to conduct pulverizing of the mixed particles because of homogeneous dispersion of the raw material particles in the target. If the raw material particles having large particle size exist, a composition irregularity arises depending on the place. That might be the cause of abnormal discharge at sputter deposition.

Next, a granulating of the mixed particles is conducted to increase liquidity of the raw material particles and sufficiently improve filling status at press molding. Next, the granulated particles are filled in a mold of prescribed size, and then, press molding is conducted to provide a molded body.

Next, the molded body (the molded raw material particles) is heated to 1300 to 1400° C. at a temperature rising speed of 1 to 5° C./minute, the temperature is maintained for 5 to 60 hours, and then, the temperature is dropped at a temperature dropping speed of 0.1 to 3° C./minute to provide sintered body. When the temperature rising speed is less than 1° C./minute, it requires undesirable time until the temperature becomes specified value. When the temperature rising speed is more than 5° C./minute, the temperature doesn't rise with uniform temperature distribution in a furnace, and as the result, unevenness might occur in the sintered body and the sintered body might crack according to its size or have large curvature. When the sintering temperature is less than 1300° C., the density of the sintered body is not sufficiently increased. When the sintering temperature is more than 1400° C., a life of heater in the furnace becomes shorter. When the temperature maintaining time is less than 5 hours, a reaction among the raw material particles doesn't sufficiently proceed and the density of the sintered body is not sufficiently increased. When the temperature maintaining time is more than 60 hours, the energy and time are more than needed for a sufficient reaction, and then, it is undesirable because it wastes energy and time from the point of view of improvement of productivity. When the temperature dropping speed is less than 0.1° C./minute, a bulk resistance of the target undesirably increases and the temperature dropping time undesirably becomes long from the point of view of improvement of productivity. When the temperature dropping speed is more than 3° C./minute, such a problem that the target is easy to crack arises.

In the method for manufacturing the sputtering target comprising In, Ta and Ti, of the present application, it is preferable that the raw material particles comprise Ta₂O₅ and TiO₂, and each of Ta₂O₅ and TiO₂ has an average particle diameters D50 of 2.0 μm or less and a BET specific surface area of 2.0 m²/g or more. When the raw material particles comprise Ta₂O₅ and TiO₂, and each of Ta₂O₅ and TiO₂ has an average particle diameters D50 of 2.0 μm or less and a BET specific surface area of 2.0 m²/g or more, the number of a phase having excellent dispersability of Ti or Ta, having high density of Ta or Ti and having a maximum diameter of 5 μm or more is 3 or less within a view of 50 μm×50 μm image. With this structure, an irregular color in appearance of the target can be reduced and uniform composition of a film produced by sputtering method can be obtained. It is preferable that each of Ta₂O₅ and TiO₂ has an average particle diameters D50 of 1.0 μm or less and a BET specific surface area of 4.0 m²/g or more. A lower limit of the average particle diameters D50 of Ta₂O₅ and TiO₂ is not especially limited, but for example, it might be 0.1 μm or more. An upper limit of the BET specific surface area is not especially limited, but for example, it might be 20.0 m²/g or less.

In the method for manufacturing the sputtering target comprising In, Ta, Ti and Sn, of the present application, it is preferable that the raw material particles comprise Ta₂O₅, TiO₂ and SnO₂, and each of Ta₂O₅, TiO₂ and SnO₂ has an average particle diameters D50 of 2.0 μm or less and a BET specific surface area of 2.0 m²/g or more. When the raw material particles comprise Ta₂O₅, TiO₂ and SnO₂, and each of Ta₂O₅, TiO₂ and SnO₂ has an average particle diameters D50 of 2.0 μm or less and a BET specific surface area of 2.0 m²/g or more, the number of a phase having excellent dispersability of Ti, Ta or Sn, having high density of Ti, Ta or Sn and having a maximum diameter of 5 μm or more is 3 or less within a view of 50 μm×50 μm image. With this structure, an irregular color in appearance of the target can be reduced, uniform composition of a film produced by sputtering method can be obtained, and the oxide target in which a production of arcing is reduced at high density can be obtained. It is preferable that each of Ta₂O₅, TiO₂ and SnO₂ has an average particle diameters D50 of 1.0 μm or less and a BET specific surface area of 4.0 m²/g or more. A lower limit of the average particle diameters D50 of Ta₂O₅, TiO₂ and SnO₂ is not especially limited, but for example, it might be 0.1 μm or more. An upper limit of the BET specific surface area is not especially limited, but for example, it might be 20.0 m²/g or less.

With regard to the oxide sintered body manufactured by the above-mentioned manufacturing method, external cylindrical grinding in the periphery and surface grinding in the side are conducted to process to, for example, a size of a thickness of 4 to 6 mm and a diameter corresponding to a size of a sputtering equipment. Then, the produced oxide sintered body is bonded to a backing plate such as a copper plate with bonding metal such as indium system alloy to provide a sputtering target.

### <Amorphous Film and Method for Manufacturing Amorphous Film>

By sputtering a substrate with the above-mentioned sputtering target under appropriate sputtering conditions, an amorphous film having the same composition as the sputtering target which is a raw material can be produced.

### <Crystalline Film and Method for Manufacturing Crystalline Film>

By annealing the amorphous film produced by the above-mentioned method at 180° C. or more to crystallize the amorphous film, a crystalline film having the same composition as the oxide target which is a raw material can be produced. A crystallization is judged depending on whether a peak can be confirmed or not in X-ray diffraction (XRD) measurement. For example, when the maximum peak plane (222) of cubic system (Ia-3) In₂O₃ is selected and the maximum intensity between 30° to 31° in which the plane (222) appears is within one and a half times as much as the average peak intensity between 30° to 31°, it can be judged that the peak of In₂O₃ don't exist and it is amorphous.

The condition of the above-mentioned X-ray diffraction (XRD) measurement can be set as follows.
Ultima: apparatus produced by Rigaku Corporation (X-ray source: Cu ray)
Tube voltage: 40 kV
Tube current: 30 mA
Scan speed: 5°/min
Step: 0.2°

Each peak intensity is calculated by removing background from data obtained by X-ray diffraction measurement. PDXL (Sonneveld-Visser method) is used in removing the background.

### EXAMPLES

Hereinafter, description will be given based on Examples for better understanding of the present invention and its effect. It should be noted all the Examples are merely exemplary, and the present invention is not limited to the Examples.

### Manufacturing Examples 1 to 25 and Comparative Examples 1 to 8

As Examples 1 to 25 and Comparative Examples 1 to 8, indium oxide particles, tantalum oxide particles, titanium oxide particles and tin oxide particles having a composition, an average particle diameters D50 and a BET specific surface area, shown in Tables 1 to 4, were prepared and mixed, and the mixed particles were pulverized.

Next, a granulation of the mixed particles was conducted, the granulated particles were filled in a mold of prescribed size, and then, press molding was conducted to provide a molded body. Next, the molded particle body was heated to sintering temperature at prescribed temperature rising speed in accordance with sintering temperatures and sintering conditions shown in Tables 2 and 4. Next, the temperature was maintained for prescribed hours, and then, the temperature was dropped at a prescribed temperature dropping speed to conduct sintering and provide sputtering targets.

### Evaluation

Atom Ratio (at %) of Each Element in Sputtering Target

An atom ratio (at %) of Ta, Ti and Sn in the sputtering target was provided by a measurement with ICP method. Further, an atom ratio of In was provided by subtracting the atom ratio (at %) of Ta, Ti and Sn from a whole.

Area Analysis with FE-EPMA

An area analysis of the sputtering target with FE-EPMA was conducted. Specifically, when a structure image of the sputtering target was observed by the area analysis of Ta, Ti or Sn with FE-EPMA, In₂O₃ and SnO₂ phase which was a parent phase and a phase having higher density of Ta, Ti or Sn in the parent phase were identified. Next, analysis value of density of Ta, Ti or Sn in the phase having higher density of Ta, Ti or Sn and analysis value of density of Ta, Ti or Sn in a phase surrounding it were compared. As the result, a phase, having analysis value ratio of density of Ta, Ti or Sn between the phase having higher density of Ta, Ti or Sn and the phase surrounding it (the analysis value ratio of density=the density in the phase having higher density of Ta, Ti or Sn/the density in the phase surrounding it) being 5 or more, was defined to be “the phase having high density of Ta, Ti or Sn”. “The phase having high density of Ta, Ti or Sn” was defined to be sub-phase and the phase surrounding the sub-phase was defined to be main phase. Further, the number of the sub-phase having a maximum diameter of 5 μm or more in the target was evaluated within a view of 50 μm×50 μm SEM image.

Relative Density

A relative density of the sputtering target was measured. The relative density was calculated by the formula: (actual measurement density/true density)×100 (%). The actual measurement density was measured by Archimedes method. The true density was substituted by weight average from mixture ratio of each oxide used as raw materials. The true density was calculated by converting analysis value (weight % ratio) of each element in the target to each oxide of In₂O₃, SnO₂, TiO₂, Ta₂O₅. The density of each oxide used In₂O₃: 7.18 g/cm³, SnO₂: 6.95 g/cm³, Ta₂O₅: 8.74 g/cm³, TiO₂: 4.26 g/cm³.

Bulk Resistance of Sputtering Target

A bulk resistance of the sputtering target was measured by four-point probe method. An apparatus used in the measurement was as follows.
Resistance measuring instruments manufactured by SPS corporation (model number: Σ-5+, manufacturing number: 15008279)
Probe: four-point probe (FELL-TL-100-SB-Σ-5+)
Fixture: RG-5

Tables 1 to 4 shows manufacturing conditions and evaluation results.

TABLE 1

| | | | | atom ratio of target [at %] | | | ZZ | ZZ | area analysis with FE-EPMA: |
|---|---|---|---|---|---|---|---|---|---|
| | | | | In/ | Ta/ | Ti/ | relative | bulk | the number of phase |
| | raw material [mol %] | | | (In + | (In + | (In + | density | resistance | having a maximum |
| | In₂O₃ | Ta₂O₅ | TiO₂ | Ti + Ta) | Ti + Ta) | Ti + Ta) | (%) | (μΩ · cm) | diameter of 5 μm or more |
| Example1 | 97.97 | 0.31 | 1.72 | 98.82 | 0.31 | 0.87 | 99.05 | 523 | 0 |
| Example2 | 97.97 | 0.31 | 1.72 | 98.82 | 0.31 | 0.87 | 99.05 | 515 | 0 |
| Example3 | 97.97 | 0.31 | 1.72 | 98.82 | 0.31 | 0.87 | 99.02 | 595 | 0 |
| Example4 | 97.97 | 0.31 | 1.72 | 98.82 | 0.31 | 0.87 | 99.42 | 561 | 0 |
| Example5 | 98.50 | 0.12 | 1.38 | 99.18 | 0.13 | 0.69 | 98.90 | 514 | 0 |
| Example6 | 98.50 | 0.12 | 1.38 | 99.18 | 0.13 | 0.69 | 98.90 | 503 | 0 |
| Example7 | 97.17 | 0.43 | 2.40 | 98.35 | 0.44 | 1.21 | 98.57 | 522 | 1 |
| Example8 | 99.55 | 0.09 | 0.36 | 99.73 | 0.09 | 0.18 | 98.55 | 685 | 0 |
| Example9 | 98.19 | 0.09 | 1.72 | 99.04 | 0.09 | 0.87 | 98.68 | 624 | 0 |
| Example10 | 99.33 | 0.31 | 0.36 | 99.51 | 0.31 | 0.18 | 98.55 | 664 | 0 |
| Example11 | 97.33 | 0.30 | 2.37 | 98.48 | 0.31 | 1.21 | 98.72 | 582 | 1 |
| Example12 | 97.84 | 0.44 | 1.72 | 98.69 | 0.44 | 0.87 | 98.62 | 533 | 1 |
| Example13 | 97.97 | 0.31 | 1.72 | 98.82 | 0.31 | 0.87 | 98.75 | 612 | 5 |
| Example14 | 97.97 | 0.31 | 1.72 | 98.82 | 0.31 | 0.87 | 98.70 | 643 | 6 |
| Example15 | 97.97 | 0.31 | 1.72 | 98.82 | 0.31 | 0.87 | 98.48 | 599 | 6 |
| Comparative | 99.35 | 0.65 | 0.00 | 99.35 | 0.65 | 0.00 | 98.35 | 521 | 0 |
| Example1 | | | | | | | | | |
| Comparative | 97.04 | 0.00 | 2.96 | 98.50 | 0.00 | 1.50 | 98.27 | 683 | 0 |
| Example2 | | | | | | | | | |
| Comparative | 96.97 | 0.46 | 2.57 | 98.23 | 0.47 | 1.30 | 98.41 | 587 | 0 |
| Example3 | | | | | | | | | |
| Comparative | 100.00 | 0.00 | 0.00 | 100.00 | 0.00 | 0.00 | 96.10 | 2270 | 0 |
| Example4 | | | | | | | | | |

TABLE 2

| | | | | | | sintering conditions | | |
|---|---|---|---|---|---|---|---|---|
| | particle characteristic of raw material | | | | ZZ | | temperature | temperature |
| | Ta₂O₅ | | TiO₂ | | sintering | temperature | maintaining | dropping |
| | D50 | BET | D50 | BET | temperature | rising speed | time | speed |
| | (μm) | (m² · g) | (μm) | (m² · g) | (° C.) | (° C./min) | (h) | (° C./min) |
| Example1 | 0.98 | 2.52 | 1.62 | 2.56 | 1350 | 3 | 20 | 3 |
| Example2 | 0.98 | 2.52 | 1.62 | 2.56 | 1350 | 3 | 10 | 3 |
| Example3 | 0.98 | 2.52 | 1.62 | 2.56 | 1350 | 3 | 10 | 0.1 |
| Example4 | 0.90 | 2.60 | 1.58 | 2.50 | 1350 | 3 | 15 | 3 |
| Example5 | 1.00 | 2.50 | 1.61 | 2.52 | 1350 | 3 | 20 | 3 |
| Example6 | 1.00 | 2.50 | 1.61 | 2.52 | 1400 | 3 | 10 | 3 |
| Example7 | 1.11 | 2.25 | 1.60 | 2.60 | 1350 | 3 | 20 | 3 |
| Example8 | 0.98 | 2.52 | 1.62 | 2.56 | 1350 | 3 | 10 | 3 |
| Example9 | 1.02 | 2.58 | 1.61 | 2.54 | 1350 | 3 | 10 | 3 |
| Example10 | 0.99 | 2.59 | 1.6 | 2.57 | 1350 | 3 | 10 | 3 |
| Example11 | 1.00 | 2.50 | 1.61 | 2.52 | 1350 | 3 | 10 | 3 |
| Example12 | 0.90 | 2.60 | 1.58 | 2.50 | 1350 | 3 | 10 | 3 |
| Example13 | 2.71 | 0.60 | 1.60 | 2.60 | 1350 | 3 | 10 | 3 |
| Example14 | 0.99 | 2.53 | 2.54 | 1.37 | 1350 | 3 | 10 | 3 |
| Example15 | 1.61 | 2.52 | 1.00 | 2.50 | 1500 | 3 | 10 | 0.1 |
| Comparative | 1.12 | 2.24 | / | / | 1350 | 3 | 10 | 3 |
| Example1 | | | | | | | | |
| Comparative | / | / | 1.67 | 2.45 | 1350 | 3 | 10 | 3 |
| Example2 | | | | | | | | |
| Comparative | 0.97 | 2.55 | 1.61 | 2.47 | 1350 | 3 | 10 | 3 |
| Example3 | | | | | | | | |
| Comparative | / | / | / | / | 1350 | 3 | 10 | 3 |
| Example4 | | | | | | | | |

TABLE 3

| | | | | | | | | | | | area analysis with FE-EPMA: |
|---|---|---|---|---|---|---|---|---|---|---|---|
| | | | | | atom ratio of target [at %] | | | | ZZ | | the number of |
| | | | | | In/ | Ta/ | Ti/ | Sn/ | relative | bulk | phase having a |
| | raw material [mol %] | | | | (In + Ti + | (In + Ti + | (In + Ti + | (In + Ti + | density | resistance | maximum diameter of 5 |
| | In₂O₃ | Ta₂O₅ | TiO₂ | SnO₂ | Ta + Sn) | Ta + Sn) | Ta + Sn) | Ta + Sn) | (%) | (μΩ · cm) | μm or more |
| Example16 | 97.64 | 0.12 | 1.70 | 0.54 | 98.72 | 0.13 | 0.87 | 0.28 | 99.06 | 443 | 0 |
| Example17 | 97.64 | 0.12 | 1.70 | 0.54 | 98.72 | 0.13 | 0.87 | 0.28 | 98.45 | 422 | 0 |
| Example18 | 96.46 | 0.43 | 2.35 | 0.75 | 97.98 | 0.44 | 1.20 | 0.38 | 98.54 | 457 | 2 |
| Example19 | 97.10 | 0.43 | 1.71 | 0.75 | 98.31 | 0.44 | 0.87 | 0.38 | 98.60 | 428 | 1 |
| Example20 | 96.76 | 0.13 | 2.35 | 0.75 | 98.29 | 0.13 | 1.20 | 0.38 | 98.58 | 460 | 1 |
| Example21 | 99.35 | 0.09 | 0.36 | 0.20 | 99.63 | 0.09 | 0.18 | 0.10 | 98.54 | 512 | 0 |
| Example22 | 97.99 | 0.09 | 1.72 | 0.20 | 98.94 | 0.09 | 0.87 | 0.10 | 98.62 | 499 | 0 |
| Example23 | 99.31 | 0.13 | 0.36 | 0.20 | 99.59 | 0.13 | 0.18 | 0.10 | 98.71 | 557 | 0 |
| Example24 | 97.62 | 0.12 | 1.70 | 0.54 | 98.72 | 0.13 | 0.87 | 0.28 | 98.72 | 456 | 5 |
| Example25 | 97.62 | 0.12 | 1.70 | 0.54 | 98.72 | 0.13 | 0.87 | 0.28 | 98.72 | 481 | 6 |
| Comparative | 99.35 | 0.00 | 0.00 | 0.65 | 99.40 | 0.00 | 0.00 | 0.60 | 97.53 | 433 | 0 |
| Example5 | | | | | | | | | | | |
| Comparative | 97.45 | 0.86 | 1.04 | 0.65 | 97.25 | 0.65 | 1.50 | 0.60 | 97.61 | 549 | 0 |
| Example6 | | | | | | | | | | | |
| Comparative | 96.97 | 0.13 | 1.69 | 1.18 | 98.40 | 0.13 | 0.87 | 0.60 | 98.24 | 467 | 0 |
| Example7 | | | | | | | | | | | |
| Comparative | 98.34 | 0.35 | 0.09 | 1.21 | 99.12 | 0.09 | 0.18 | 0.61 | 98.35 | 546 | 0 |
| Example8 | | | | | | | | | | | |

TABLE 4

| | | | | | | | | sintering conditions | | |
|---|---|---|---|---|---|---|---|---|---|---|
| | particle characteristic of raw material | | | | | | ZZ | | temperature | temperature |
| | Ta₂O₅ | | TiO₂ | | SnO₂ | | sintering | temperature | maintaining | dropping |
| | D50 | BET | D50 | BET | D50 | BET | temperature | rising speed | time | speed |
| | (μm) | (m² · g) | (μm) | (m² · g) | (μm) | (m² · g) | (° C.) | (° C./min) | (h) | (° C./min) |
| Example16 | 0.99 | 2.49 | 1.64 | 2.50 | 1.25 | 5.46 | 1350 | 3 | 20 | 3 |
| Example17 | 0.99 | 2.49 | 1.64 | 2.50 | 1.25 | 5.46 | 1500 | 3 | 20 | 3 |
| Example18 | 1.01 | 2.41 | 1.61 | 2.55 | 1.26 | 5.42 | 1350 | 3 | 10 | 3 |
| Example19 | 0.98 | 2.65 | 1.60 | 2.56 | 1.25 | 5.44 | 1350 | 3 | 10 | 3 |
| Example20 | 1.10 | 2.41 | 1.62 | 2.51 | 1.25 | 5.44 | 1350 | 3 | 10 | 3 |
| Example21 | 1.08 | 2.48 | 1.63 | 2.48 | 1.29 | 5.40 | 1350 | 3 | 10 | 3 |
| Example22 | 0.95 | 2.63 | 1.64 | 2.44 | 1.29 | 5.40 | 1350 | 3 | 10 | 3 |
| Example23 | 1.00 | 2.46 | 1.60 | 2.56 | 1.27 | 5.42 | 1350 | 3 | 10 | 3 |
| Example24 | 0.99 | 2.53 | 1.60 | 2.60 | 2.87 | 1.13 | 1350 | 3 | 10 | 3 |
| Example25 | 2.71 | 0.60 | 2.54 | 1.37 | 2.87 | 1.13 | 1350 | 3 | 10 | 3 |
| Comparative | / | / | / | / | 1.23 | 5.49 | 1350 | 3 | 10 | 3 |
| Example5 | | | | | | | | | | |
| Comparative | 1.12 | 2.24 | 1.67 | 2.45 | 1.23 | 5.49 | 1350 | 3 | 10 | 3 |
| Example6 | | | | | | | | | | |
| Comparative | 0.98 | 2.60 | 1.68 | 2.49 | 1.24 | 5.43 | 1350 | 3 | 10 | 3 |
| Example7 | | | | | | | | | | |
| Comparative | 1.04 | 2.43 | 1.60 | 2.56 | 1.20 | 5.49 | 1350 | 3 | 10 | 3 |
| Example8 | | | | | | | | | | |

1. A sputtering target, being an oxide target, comprising In, Ta and Ti,
wherein a content of Ta satisfies Ta/(In+Ta+Ti)=0.08 to 0.45 at %, and
a content of Ti satisfies Ti/(In+Ta+Ti)=0.03 to 1.25 at %.

2. The sputtering target according to claim 1, having a relative density of 98.5% or more.

3. The sputtering target according to claim 1, having a relative density of 98.8% or more.

4. (canceled)

5. The sputtering target according to claim 1,
wherein the number of a phase having high density of Ta or Ti in an area analysis with FE-EPMA and having a maximum diameter of 5 μm or more is 3 or less within a view of 50 μm×50 μm SEM image.

6. A method for manufacturing the sputtering target according to claim 1, comprising
a step of molding raw material particles, and
a step of sintering the molded raw material particles comprising,
a step of heating the molded raw material particles to 1300 to 1400° C. at a temperature rising speed of 1 to 5° C./minute,
a step of maintaining the temperature for 5 to 60 hours, and
a step of dropping the temperature at a temperature dropping speed of 0.1 to 3° C./minute.

7. The method for manufacturing the sputtering target according to claim 6,
wherein the raw material particles comprise Ta₂O₅ and TiO₂, each of Ta₂O₅ and TiO₂ having an average particle diameters D50 of 2.0 μm or less and a BET specific surface area of 2.0 m²/g or more.

8. A sputtering target, being an oxide target, comprising In, Ta, Ti and Sn,
wherein a content of Ta satisfies Ta/(In+Ta+Ti+Sn)=0.08 to 0.45 at %,
a content of Ti satisfies Ti/(In+Ta+Ti+Sn)=0.03 to 1.25 at %, and
a content of Sn satisfies Sn/(In+Ta+Ti+Sn)=0.04 to 0.40 at %.

9. The sputtering target according to claim 8, having a relative density of 98.5% or more.

10. The sputtering target according to claim 8, having a relative density of 98.8% or more.

11. (canceled)

12. The sputtering target according to claim 8,
wherein the number of a phase having high density of Ta, Ti or Sn in an area analysis with FE-EPMA and having a maximum diameter of 5 μm or more is 3 or less within a view of 50 μm×50 μm SEM image.

13. A method for manufacturing the sputtering target according to claim 8, comprising
a step of molding raw material particles, and
a step of sintering the molded raw material particles comprising,
a step of heating the molded raw material particles to 1300 to 1400° C. at a temperature rising speed of 1 to 5° C./minute,
a step of maintaining the temperature for 5 to 60 hours, and
a step of dropping the temperature at a temperature dropping speed of 0.1 to 3° C./minute.

14. The method for manufacturing the sputtering target according to claim 13,
wherein the raw material particles comprise Ta₂O₅, TiO₂ and SnO₂, each of Ta₂O₅, TiO₂ and SnO₂ having an average particle diameters D50 of 2.0 μm or less and a BET specific surface area of 2.0 m²/g or more.

15. (canceled)

16. An amorphous film having the same composition with the sputtering target according to claim 1.

17. (canceled)

18. A crystalline film having the same composition with the sputtering target according to claim 1.

19. An amorphous film having the same composition with the sputtering target according to claim 8.

20. A crystalline film having the same composition with the sputtering target according to claim 8.
